(19) United States
(12) Patent Application Publication
(10) Pub. No.: US 2026/0247896 A1
(43) Pub. Date: Aug. 20, 2026

(54) METHOD FOR CLEANING SEMICONDUCTOR CHIP AND METHOD FOR MANUFACTURING SEMICONDUCTOR DEVICE

(71) Applicant: Resonac Corporation, Tokyo (JP)

(72) Inventors: Hiroyoshi DEGUCHI, Tokyo (JP); Tatsuya MAKINO, Tokyo (JP); Seiji KAI, Tokyo (JP); Toshiaki SHIRASAKA, Tokyo (JP); Tomohito MOROSAKI, Tokyo (JP); Chikashi AOYAGI, Tokyo (JP); Kazuhiro SASAKI, Tokyo (JP); Takehiro KINOSHITA, Tokyo (JP); Koji NAODA, Tokyo (JP)

(21) Appl. No.: 19/480,342

(22) PCT Filed: Apr. 25, 2024
(86) PCT No.: PCT/JP2024/016316

§ 371 Date: Oct. 30, 2025

(30) Foreign Application Priority Data
May 1, 2023 (JP) 2023-075732

(51) Int. Cl. H10P 70/00; H10P 52/00; H10P 54/20; H10P 58/00; H10P 72/70

(52) U.S. Cl. CPC H10P 70/30; H10P 52/00; H10P 54/20; H10P 58/00; H10P 72/7402; H10P 72/7416; H10P 72/7434

(57) ABSTRACT

A method for cleaning a semiconductor chip, the method including: (a) cleaning a plurality of semiconductor chips with a chemical solution, the semiconductor chips being arranged in a region on a surface of an adhesive film in which the region is inside a dicing ring attached to the surface of the adhesive film; and (b) picking up the cleaned semiconductor chips from the surface, in which the chemical solution is one kind selected from the group consisting of solvent-based, acid-based, and alkaline-based chemical solutions. A method for manufacturing a semiconductor device, the method including bonding semiconductor chip having been cleaned by the method for a semiconductor chip to an adherend.

### TECHNICAL FIELD

The present disclosure relates to a method for cleaning a semiconductor chip and a method for manufacturing a semiconductor device.

### BACKGROUND ART

Conventionally, semiconductor devices have been manufactured through the following steps. First, a semiconductor wafer is attached to an adhesive sheet for dicing, and in this state, the semiconductor wafer is singulated into semiconductor chips (a dicing step). Thereafter, a step of picking the semiconductor chips, a step of bonding the semiconductor chips to an adherend (for example, a substrate), and the like are performed. Along with multifunctionalization of various devices, stacked MCPs (Multi Chip Package), in which semiconductor elements are stacked in multiple stages to increase the capacity, have become widespread. In order to realize a more advanced three-dimensional integration technology, for example, hybrid bonding to connect heterogeneous devices has also been developed. Patent Literature 1 discloses that a plurality of semiconductor chips are bonded to a substrate by hybrid bonding.

### CITATION LIST

### Patent Literature

Patent Literature 1: Japanese Unexamined Patent Publication No. 2001-197431

### SUMMARY OF INVENTION

### Technical Problem

By the way, the present inventors have conducted studies from various viewpoints in order to implement an advanced three-dimensional integration technology such as hybrid bonding, and as a result, have found that it is useful to more highly clean semiconductor chips than before, prior to bonding the semiconductor chips to an adherend. In the manufacturing process of a semiconductor device, for example, contaminant such as cutting swarf may be generated in a step of thinning a semiconductor wafer and a step of dicing the same, so that the semiconductor chips to which contaminant adheres are subjected to the next step. For example, in hybrid bonding, different types of devices are often bonded to each other through the surfaces thereof, and when contaminant remains between the two surfaces, even fine contaminant causes a decrease in the connection reliability of the semiconductor devices.

The present disclosure provides a method for cleaning a semiconductor chip capable of efficiently and highly removing contaminant that adheres to semiconductor chips in the manufacturing process of a semiconductor device. The present disclosure also provides a method for manufacturing a semiconductor device using a semiconductor chip cleaned by the method.

### Solution to Problem

One aspect of the present disclosure relates to a method for cleaning a semiconductor chip. The method includes: (a) cleaning a plurality of semiconductor chips with a chemical solution, the semiconductor chips being arranged in a region provided on a surface of an adhesive film and inside a dicing ring attached to the surface; and (b) picking up the cleaned semiconductor chips from the surface, wherein the chemical solution is one type selected from the group consisting of solvent type, acid type, and alkaline type.

Conventionally, on the surface of an adhesive film to which a dicing ring is attached (also referred to as “dicing tape”), semiconductor chips are cleaned using water, but semiconductor chips are not cleaned using chemical solutions. That is, for example, when semiconductor chips are bonded to a substrate via bumps formed on the semiconductor chips, there has been no problem in cleaning with water. On the other hand, the present invention, by cleaning semiconductor chips on an adhesive film with a chemical solution, is capable of highly removing contaminant that has adhered to the semiconductor chips through the previous various processes. The use of highly cleaned semiconductor chips can realize the excellent connection reliability of semiconductor devices manufactured by applying advanced three-dimensional integration technologies.

The cleaning method is also useful in that the cleaning method can be efficiently performed in the manufacturing process of a semiconductors. That is, in the manufacturing process of a semiconductor device, it is not efficient that semiconductor chips are conveyed to a facility for highly cleaning the semiconductor chips, and the semiconductor chips cleaned therein are returned to the facility for mounting the same. On the other hand, according to the present invention, since thorough cleaning with a chemical solution is performed on the surface of an adhesive film and in a state where the adhesive film has a dicing ring adhered thereto, it is possible to pick up the cleaned semiconductor chips and supply them as they are to the next process.

One aspect of the present disclosure relates to a method for manufacturing a semiconductor device. The method includes bonding semiconductor chips having been subjected to performing the above-mentioned method for cleaning a semiconductor chip to an object to be bonded. The method, using highly cleaned semiconductor chips, is capable of manufacturing a semiconductor device having excellent connection reliability.

### Advantageous Effects of Invention

The present disclosure provides a method for cleaning a semiconductor chip capable of efficiently and highly removing contaminant that adheres to semiconductor chips in the manufacturing process of a semiconductor device. The present disclosure also provides a method for manufacturing a semiconductor device using a semiconductor chip cleaned by the method.

### BRIEF DESCRIPTION OF DRAWINGS

FIG. 1 is a cross-sectional view schematically illustrating a state in which preparation has been made to perform the cleaning method according to the present disclosure.

FIG. 2 is a cross-sectional view schematically illustrating a state in which a cleaned semiconductor chip is being picked up.

FIG. 3 (a) to (c) in FIG. 3 are cross-sectional views schematically illustrating a process of manufacturing a semiconductor device by the method according to the first embodiment.

FIG. 4 (a) to (c) in FIG. 4 are cross-sectional views schematically illustrating a process of manufacturing a semiconductor device by the method according to the first embodiment.

FIG. 5 is a cross-sectional view schematically illustrating a state in which tension is applied to an adhesive film to widen the space between two adjacent semiconductor chips.

FIG. 6 is a cross-sectional view schematically illustrating a state in which one semiconductor chip is bonded on a substrate.

FIG. 7 is a cross-sectional view schematically illustrating a state in which a plurality of semiconductor chips is stacked on a substrate.

FIG. 8 is a cross-sectional view schematically illustrating an example of a semiconductor device having a configuration in which a plurality of semiconductor chips are stacked.

FIG. 9 (a) and (b) in FIG. 9 are cross-sectional views schematically illustrating processes of manufacturing a semiconductor device by the method according to the second embodiment.

FIG. 10 (a) and (b) in FIG. 10 are cross-sectional views schematically illustrating processes of manufacturing a semiconductor device by the method according to the second embodiment.

FIG. 11 (a) and (b) in FIG. 11 are cross-sectional views schematically illustrating a process of manufacturing a semiconductor device by the method according to the third embodiment.

FIG. 12 (a) and (b) in FIG. 12 are cross-sectional views schematically illustrating processes of manufacturing a semiconductor device by the method according to the third embodiment.

FIG. 13 (a) and (b) in FIG. 13 are cross-sectional views schematically illustrating processes of manufacturing a semiconductor device by the method according to the fourth embodiment.

FIG. 14 (a) to (c) in FIG. 14 are cross-sectional views schematically illustrating processes of manufacturing a semiconductor device by the method according to the fifth embodiment.

### DESCRIPTION OF EMBODIMENTS

Hereinafter, embodiments of the present disclosure will be described in detail with reference to the drawings. However, the present disclosure is not limited to the following embodiments. In the following embodiments, the components (including steps and the like) are not essential unless otherwise specified. In the following description, the same or corresponding parts are denoted by the same reference numerals, and redundant description is omitted. Further, unless otherwise specified, the positional relationship such as upper, lower, left, and right is based on the positional relationship illustrated in the drawings. The sizes of the components in the drawings are conceptual, and the dimensional ratios in the drawings are not limited to the depicted ratios.

Numerical values and ranges thereof in the present specification are not intended to limit the present disclosure. In the present specification, a numerical range indicated using “to” indicates a range including the numerical values described before and after “to” as a minimum value and a maximum value, respectively. In numerical ranges described in a stepwise manner in the present description, the upper limit value or the lower limit value described in one numerical range may be replaced with the upper limit value or the lower limit value of another numerical range described in a stepwise manner.

### A Method for Cleaning Semiconductor Chip

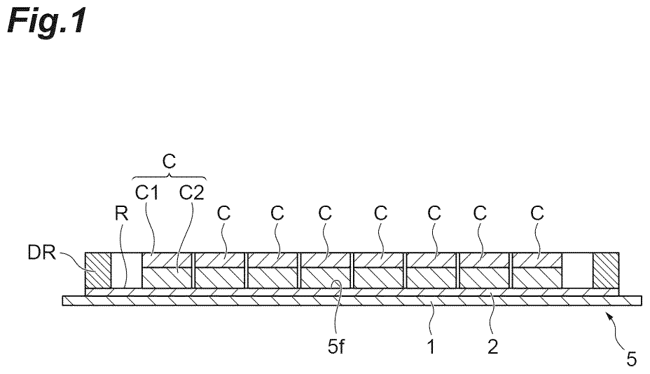

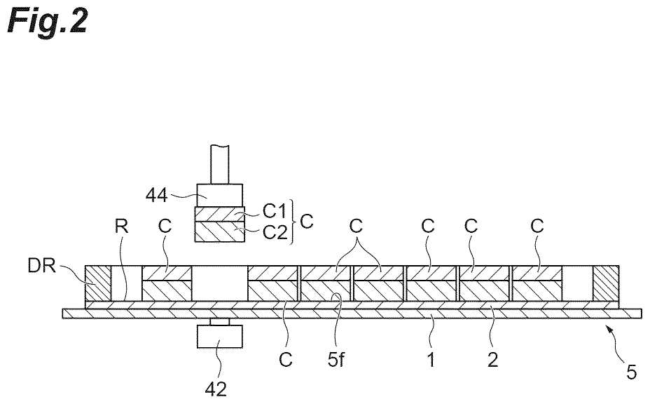

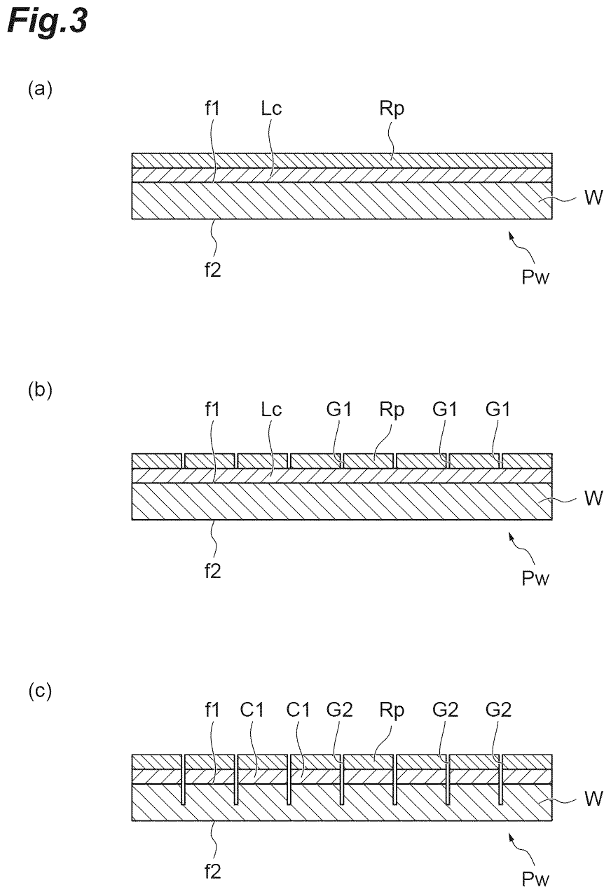

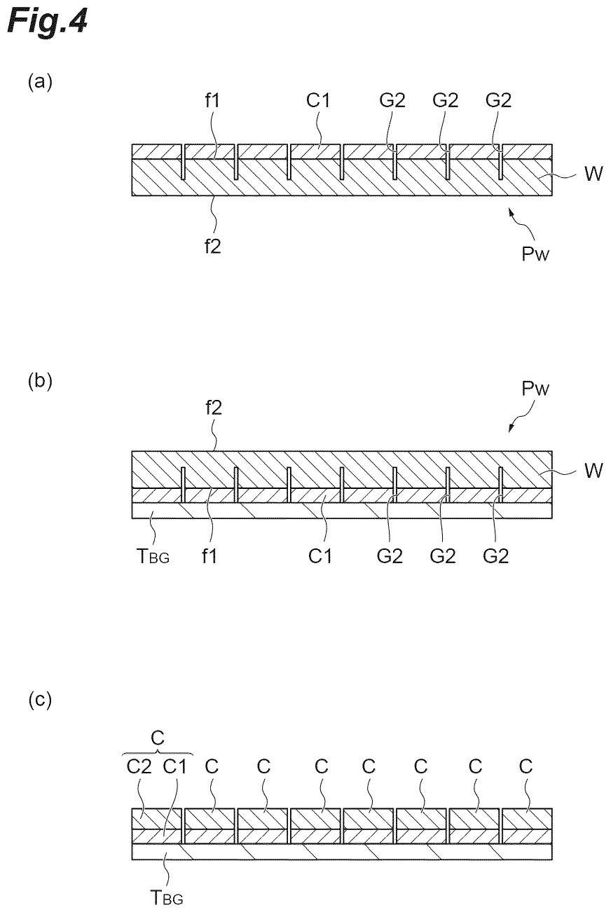

The method for cleaning a semiconductor chip according to the embodiment will be described with reference to FIGS. 1 and 2. FIG. 1 is a cross-sectional view schematically illustrating a state in which preparations have been made to perform the cleaning method according to the present embodiment. A plurality of semiconductor chips C illustrated in FIG. 1 are targets to be cleaned. FIG. 2 is a cross-sectional view schematically illustrating a state in which a cleaned semiconductor chip C is being picked up. The semiconductor chip C is obtained through a step of singulating a workpiece Pw illustrated in (a) in FIG. 3, and includes a circuit layer C1 and a die C2. The circuit layer C1 is obtained by singulating a circuit layer Lc, and the die C2 is obtained by singulating a semiconductor wafer W (see (c) in FIG. 4).

The cleaning method according to the embodiment includes the following steps:
(a) cleaning a plurality of semiconductor chips C with a chemical solution, the semiconductor chips being arranged in a region R provided on a surface 5f of an adhesive film 5 and inside a dicing ring DR affixed to the surface 5f; and
(b) picking up the cleaned semiconductor chip C from the surface.

As illustrated in FIG. 1, semiconductor chips C are arranged in the region R surrounded by the dicing ring DR. The specific method for cleaning the semiconductor chip C is not particularly limited, and for example, the semiconductor chip C is cleaned by spraying a chemical solution from a nozzle toward the semiconductor chip C. Examples of the chemical solution include a solvent type, an acid type, and an alkaline type.

The chemical solution of solvent type contains, for example, NMP (N-methyl-2-pyrrolidone), MEK (methyl ethyl ketone), PGMEA (propylene glycol monomethyl ether acetate), DMSO (dimethyl sulfoxide), or cyclopentanone, and can highly remove contaminant such as cutting swarf, grinding swarf, processing swarf, and debris from the semiconductor chip C.

The chemical solution of acid type contains, for example, sulfuric acid, citric acid, or hydrofluoric acid, and can highly remove contaminant such as cutting swarf, grinding swarf, processing swarf, and debris from the semiconductor chip C.

The chemical solution of alkaline type contains, for example, potassium hydroxide, sodium hydroxide, ammonium hydroxide, sodium hydrogen carbonate, hydroxylamine, TMAH (tetramethylammonium=hydroxide), or ammonia water, and can highly remove contaminant such as cutting swarf, grinding swarf, processing swarf, and debris from the semiconductor chip C.

The adhesive film 5 includes a base film 1 and an adhesive layer 2 formed on the surface of the base film 1. Examples of the base film 1 include plastic films such as polytetrafluoroethylene film, polyethylene terephthalate film, polyethylene film, polypropylene film, polymethylpentene film, and polyimide film. Among them, a film having resistance to a chemical solution used for cleaning the semiconductor chip C may be used. The base film 1 may be subjected to a surface treatment such as primer application, UV treatment, corona discharge treatment, polishing treatment, or etching treatment as necessary.

The adhesive layer 2 is formed through, for example, a step of applying a coating liquid containing a resin composition having an adequate adhesive force onto the surface of the base film 1. A resin composition having resistance to the chemical solution used for cleaning the semiconductor chip C may be used. The adhesive layer 2 may have a property that the adhesive force thereof is reduced by irradiation with actinic energy (for example, ultraviolet rays).

As illustrated in FIG. 2, the semiconductor chip C is pushed upward by using a push-up jig 42 to release the semiconductor chip C from the adhesive layer 2, and the semiconductor chip C is sucked and picked up by using a suction collet 44. When the adhesive force of the adhesive layer 2 is reduced by irradiation with actinic energy, the adhesive layer 2 is irradiated with an active energy ray prior to the pickup. The irradiation dose is, for example, 10 to 1000 mJ/cm² , and may be 100 to 700 mJ/cm² or 200 to 500 mJ/cm².

The cleaning method according to the embodiment, by cleaning the semiconductor chip C on the adhesive film 5 with a chemical solution, is capable of highly removing contaminant that adheres to the semiconductor chip C as compared with cleaning with water. By using the highly cleaned semiconductor chip C, a semiconductor device having excellent connection reliability can be manufactured. The cleaning method is also useful in that the cleaning method can be efficiently performed in the manufacturing process of semiconductors. That is, the cleaning method, in which thorough cleaning with a chemical solution is performed on the surface 5f of the adhesive film 5 and in a state where the adhesive film 5 has the dicing ring DR adhered thereto, is capable of picking up the cleaned semiconductor chip C and subjecting the semiconductor chip C as it is to the next step. The semiconductor chip C may be cleaned with pure water before and/or after cleaning with a chemical agent.

### A Method for Manufacturing Semiconductor Device

### First Embodiment

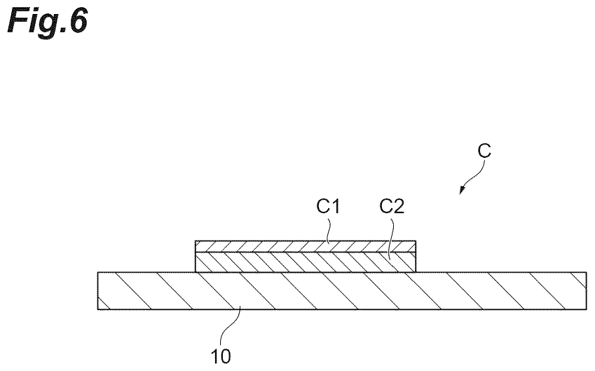

The method for manufacturing a semiconductor device including performing the cleaning method will be specifically described. The method for manufacturing a semiconductor device according to the first embodiment includes the following steps;
(1a) forming a photoresist Rp on a workpiece Pw including: a semiconductor wafer W having a first surface f1 and a second surface f2; and a circuit layer Lc formed on the first surface f1, and forming the photoresist Rp so that the photoresist Rp covers the circuit layer Lc (see (a) in FIG. 3);
(2a) exposing and developing the photoresist Rp to form a groove G1 reaching the circuit layer Lc in the photoresist Rp (see (b) in FIG. 3);
(3a) performing plasma dicing to cut the circuit layer Lc and half-cut the semiconductor wafer W through the groove G1 to form a groove G2 (see (c) in FIG. 3);
(4a) removing the photoresist Rp from the circuit layer Lc (see (a) in FIG. 4);
(5a) attaching the backgrinding tape TBG so that the backgrinding tape TBG covers the circuit layer Lc (see (b) in FIG. 4);
(6a) grinding the semiconductor wafer W from the side of the second surface f2 to obtain a plurality of semiconductor chips C on a surface of the backgrinding tape TBG (see (c) in FIG. 4);
(7a) transferring plurality of semiconductor chips C from the surface of the backgrinding tape TBG onto a surface 5f of an adhesive film 5, and attaching a dicing ring DR on the surface 5f so that the dicing ring DR surrounds the semiconductor chips C (see FIG. 1);
(8a) performing the method for cleaning a semiconductor chip; and
(9a) bonding the cleaned semiconductor chip C to an adherend (see FIG. 6).

The workpiece Pw illustrated in (a) in FIG. 3 includes a semiconductor wafer W and a circuit layer Lc. The thickness of the semiconductor wafer W is, for example, 5 to 775 μm and may be 50 to 300 μm. The diameter of the semiconductor wafer W is, for example, 50 to 300 mm and may be 150 to 300 mm. In the circuit layer Lc, various electronic circuits (for example, an integrated circuit and a power supply circuit) are formed according to the application of the semiconductor device. The thickness of the circuit layer Lc is, for example, 0.01 to 50 μm and may be 0.1 to 10 μm. The photoresist Rp is made of a photosensitive insulating material, and the groove G1 can be formed in the photoresist Rp by a photolithography process ((b) in FIG. 3).

The groove G2 illustrated in (c) in FIG. 3 penetrates the circuit layer Lc and extends from the first surface f1 to the inside of the semiconductor wafer W. The groove G2 does not reach the second surface f2. The groove G2 is formed by plasma dicing. As one type of plasma dicing, a process called Bosch process is known. In the Bosch process, a passivation step using C₄F₈ plasma and an etching step using SF₆ plasma are alternately performed to etch the silicon constituting the semiconductor wafer W. That is, in the passivation step, a fluorocarbon-based polymer film (hereinafter, simply referred to as “polymer film”) is isotropically formed on the entire inner surface of the groove G1. Thereafter, in the etching step, a bias is applied to the semiconductor wafer W, and the polymer film at the bottom of the groove G1 is removed by ion etching. On the other hand, the polymer film on the side wall of the groove G1 is not removed and constitutes the side wall of the groove G1. Only the silicon exposed at the bottom of the groove G1, from which the polymer film has been removed, is etched by fluorine radicals. By repeating these steps, groove G2 is formed. The side surface of the groove G2 thus formed is covered with a polymer film. When the polymer film is released in the subsequent process, the polymer film may become contaminant that lowers the reliability of the semiconductor device. The circuit layer Lc is singulated by the groove G2 to form a plurality of circuit layers C1.

After the step (6a), the thickness of the die C2 (the thickness of the portion excluding the circuit layer C1 from the semiconductor chip C) is, for example, 5 to 775 μm and may be 50 to 300 μm. The grinding swarf generated in the step (6a) can also become contaminant that lowers the reliability of the semiconductor device.

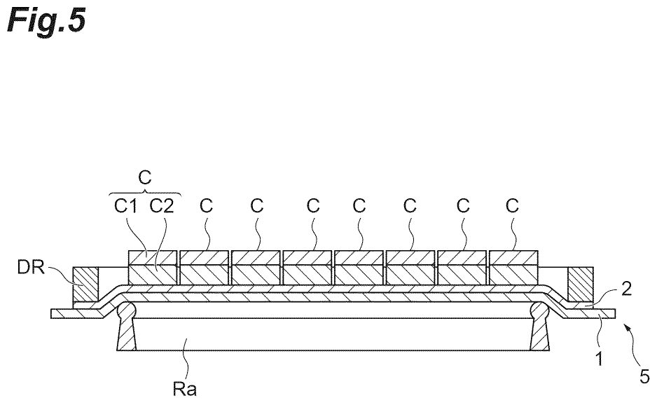

After the step (7a), prior to performing the method for cleaning a semiconductor chip, tension may be applied to the adhesive film 5 to widen the space between two adjacent semiconductor chips C. That is, as illustrated in FIG. 5, tension is applied to the adhesive film 5 by pushing up the inside of the dicing ring DR with the ring Ra from the side of the base film 1 of the adhesive film 5. As a result, in the step (8a), the chemical solution is easily supplied to the side surface of the semiconductor chip C, and the polymer film attached to the side surface can be sufficiently removed with the chemical solution. In order to remove the polymer film, a hydrofluoroether (HFE)-based or hydroxylamine (HAD)-based chemical solution is preferably used as a chemical solution. On the other hand, in order to remove grinding swarf, it is preferable to use a chemical solution of the solvent type, acid type, or alkaline type as the chemical solution.

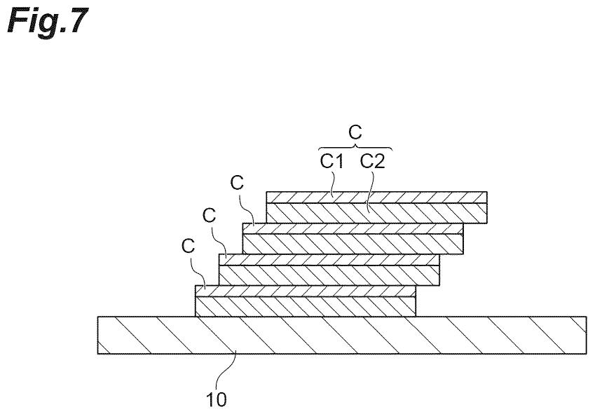

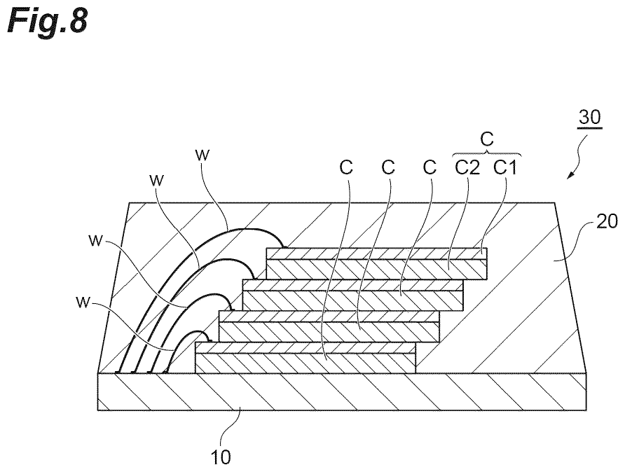

FIG. 6 is a cross-sectional view schematically illustrating a state in which the cleaned semiconductor chip C is bonded to the substrate 10 (adherend). In order to bond the semiconductor chip C to the substrate 10, for example, a die-bonding film (not illustrated) is used. As illustrated in FIG. 7, when a plurality of semiconductor chips C is stacked, the object (adherend) to which each of the semiconductor chips C of the second and subsequent stages is adhered is the semiconductor chip C of the lower stage. The semiconductor device 30 illustrated in FIG. 8 is manufactured through a step of connecting the substrate 10 and each of the semiconductor chips C through a wire w, and a step of sealing the semiconductor chips C with a resin material 20.

### Second Embodiment

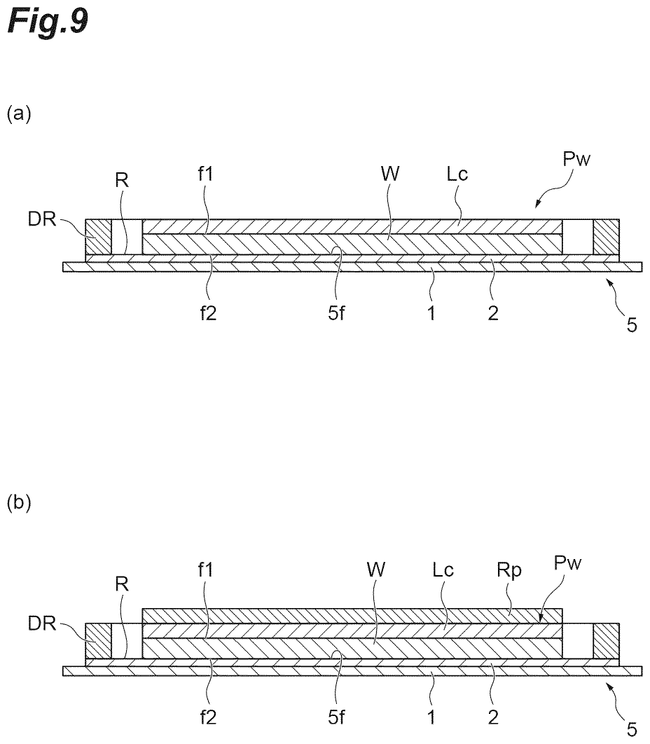

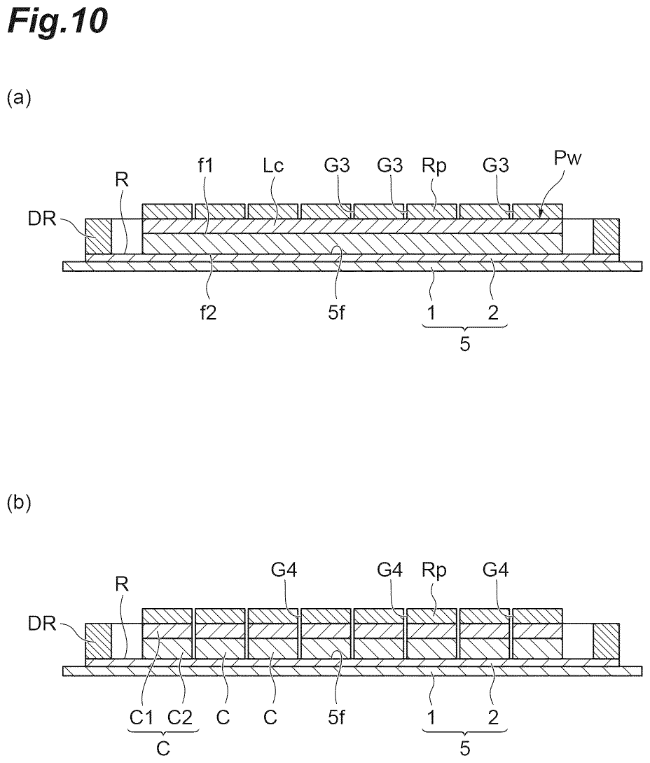

The method for manufacturing a semiconductor device according to the second embodiment includes the following steps;
(1b) arranging a workpiece Pw in a region R within a dicing ring DR attached onto the surface 5f of an adhesive film 5 (see (a) in FIG. 9);
(2b) forming a photoresist Rp so that the photoresist Rp covers the circuit layer Lc (see (b) in FIG. 9);
(3b) exposing and developing the photoresist Rp to form a groove G3 reaching the circuit layer Lc in the photoresist (see (a) in FIG. 10);
(4b) performing plasma dicing to cut the circuit layer Lc and the semiconductor wafer W through the groove G3 to obtain a plurality of semiconductor chips C on the surface 5f of the adhesive film 5 (see (b) in FIG. 10);
(5b) performing the method for cleaning a semiconductor chip (see FIGS. 1 and 2); and
(6b) bonding the cleaned semiconductor chip C to the adherend (see FIG. 6).

The embodiment will be mainly described with respect to the points of difference from the first embodiment. In the embodiment, the steps (2b) to (5b) are performed on the surface of the adhesive film 5 to which the dicing ring DR is affixed. After the step (4b), as illustrated in (b) in FIG. 10, the photoresist Rp remains on the upper surface of the semiconductor chip C. The photoresist Rp may be removed using a resist removing agent prior to performing the step (5b), or may be removed using a chemical solution in the step (5b). In order to remove the photoresist Rp, a solvent-based chemical solution (particularly, NMP) is preferably used. The groove G4 illustrated in (b) in FIG. 10 penetrates the circuit layer Lc and the semiconductor wafer W and reaches the surface 5f of the adhesive film 5. The groove G4 may be formed by plasma dicing similarly to the groove G2 described above. The polymer film resulting from the plasma dicing may be removed by using the HFE-based or HDA-based chemical solution similarly to the first embodiment.

### Third Embodiment

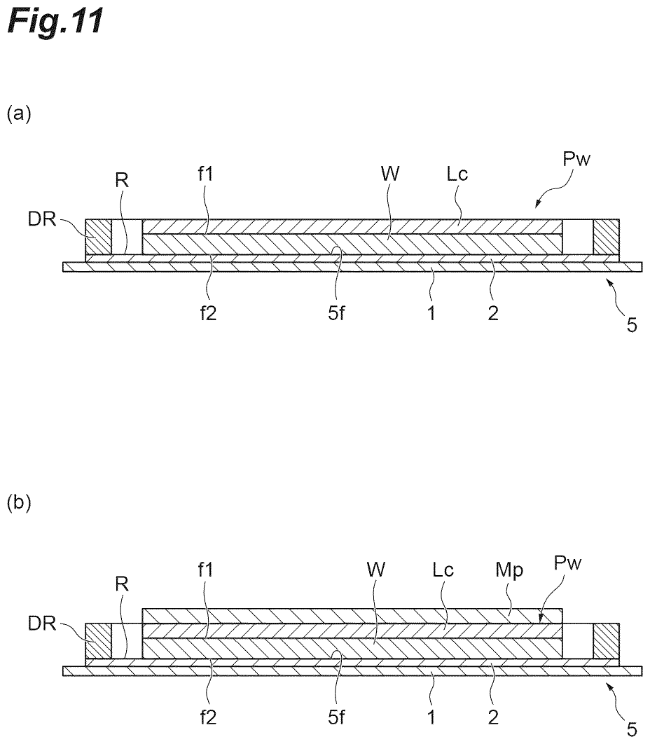

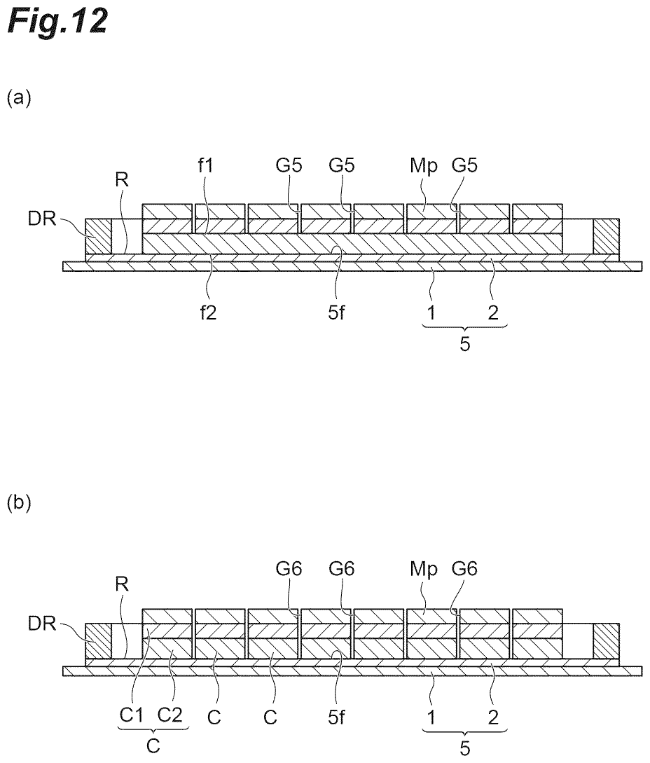

The method for manufacturing a semiconductor device according to the third embodiment includes the following steps;
(1c) arranging a workpiece Pw in a region R provided inside a dicing ring DR adhered onto the surface 5f of the adhesive film 5 (see (a) in FIG. 11);
(2c) forming the protective film Mp so that the protective film Mp covers the circuit layer Lc (see (b) in FIG. 11);
(3c) cutting the protective film Mp and the circuit layer Lc with a laser to form a groove G5 reaching the first surface f1 of the semiconductor wafer W (see (a) in FIG. 12);
(4c) performing plasma dicing to cut the semiconductor wafer W through the groove G5 to obtain a plurality of semiconductor chips C on the surface 5f of the adhesive film 5 (see (b) in FIG. 12);
(5c) performing the method for cleaning the semiconductor chip (see FIGS. 1 and 2); and
(6c) bonding the cleaned semiconductor chip C to an adherend (see FIG. 6).

The embodiment will be mainly described with respect to the points of difference from the first and second embodiments. In the embodiment, a protective film Mp is formed in the step (2c). The protective film Mp is for preventing the circuit layer Lc from being damaged. The protective film Mp is made of, for example, a water-soluble resin, and can be formed by applying a coating film containing such a resin onto the surface of the workpiece Pw. The protective film Mp remains on the upper surface of the semiconductor chip C after the step (4c) (see (b) in FIG. 12). The protective film Mp is removed by pure water in the step (5c). The groove G6 illustrated in (b) in FIG. 12 penetrates the semiconductor wafer W and reaches the surface 5f of the adhesive film 5. The groove G6 may be formed by plasma dicing similarly to the groove G2 described above. The polymer film resulting from the plasma dicing may be removed by using the HFE-based or HDA-based chemical solution similarly to the first embodiment.

In the embodiment, the groove G6 may be formed by blade dicing instead of plasma dicing. For example, when the circuit layer Lc includes a low-k film, the circuit layer Lc is cut with a laser to form the groove G5 in order to suppress peeling of the low-k film having relatively low mechanical strength. On the other hand, thereafter, the process of cutting the semiconductor wafer W (the process of forming the groove G6) may be performed by blade dicing. The low-k film is a film made of a material having a low dielectric constant, and is mainly used as an interconnect layer, that is, an insulating material between metal wiring electrically connecting different electronic components in a chip. The use of the low-k film can reduce the parasitic capacitance between wirings, thereby improving the signal transmission speed and suppressing crosstalk between wirings. The process of forming a groove in the circuit layer Lc with a laser is called laser grooving.

### Fourth Embodiment

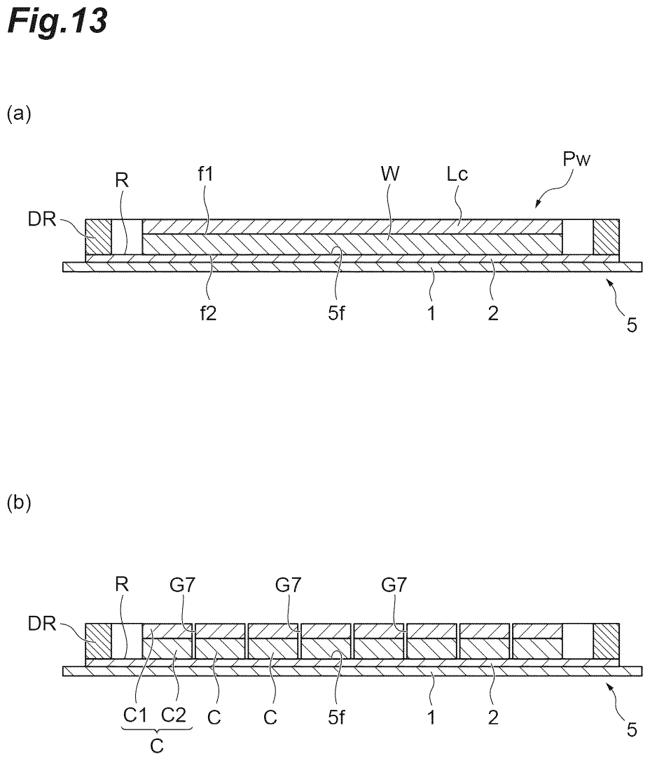

The method for manufacturing a semiconductor device according to the fourth embodiment includes the following steps;
(1d) arranging a workpiece Pw in a region R within a dicing ring DR attached onto the surface 5f of the adhesive film 5 (see (a) in FIG. 13);
(2d) performing blade dicing to cut the workpiece Pw to obtain a plurality of semiconductor chips C on the surface 5f of the adhesive film 5 (see (b) in FIG. 13);
(3d) performing the method the cleaning method for a semiconductor chip (see FIGS. 1 and 2); and
(4d) bonding the cleaned semiconductor chip to an adherend (see FIG. 6).

The embodiment will be mainly described with respect to the points of difference from the first, second, and third embodiments. In the embodiment, in the step (2d), the workpiece Pw is singulated into a plurality of semiconductor chips C by blade dicing. The groove G7 formed by blade dicing penetrates the circuit layer Lc and the semiconductor wafer W and reaches the surface 5f of the adhesive film 5. The grinding swarf generated in the step (2d) can become contaminant that lowers the reliability of the semiconductor device. In order to remove grinding swarf generated by blade dicing, the solvent-based, acid-based, or alkaline-based chemical solution is preferably used as the chemical solution. In the embodiment, a step of forming a photoresist or a protective film is unnecessary, and a step of removing them is also unnecessary.

### Fifth Embodiment

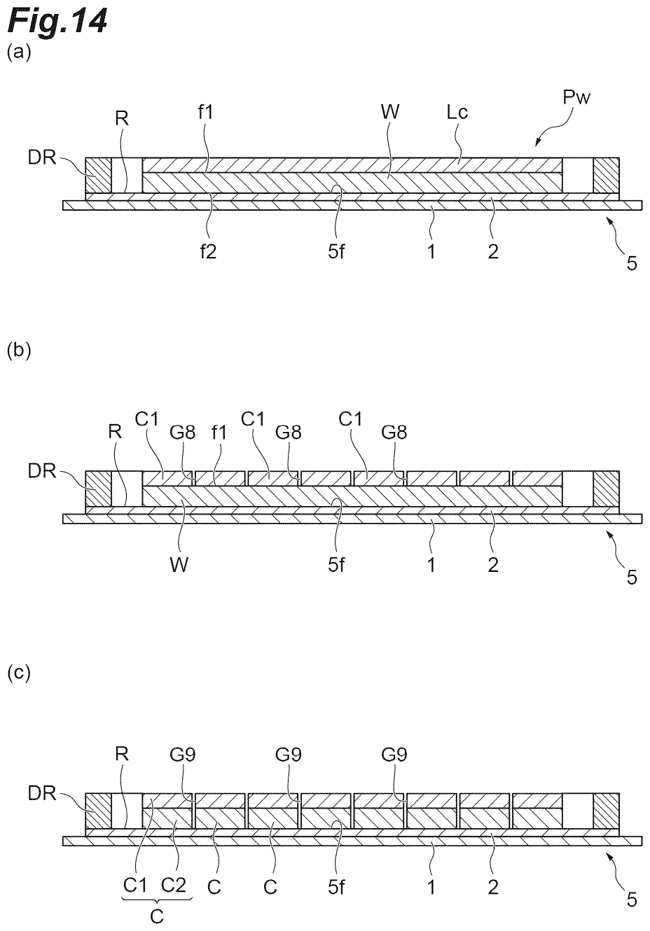

The method for manufacturing a semiconductor device according to the fifth embodiment includes the following steps;
(1e) arranging a workpiece Pw in a region R within a dicing ring DR attached onto the surface 5f of the adhesive film 5 (see (a) in FIG. 14);
(2e) cutting the circuit layer Lc with a laser to form a groove G8 reaching the first surface f1 of the semiconductor wafer W (see FIG. (b) in 14);
(3e) performing blade dicing to cut the semiconductor wafer W through the groove G8 to obtain a plurality of semiconductor chips C on the surface 5f of the adhesive film 5 (see (c) in FIG. 14);

(4e) performing the cleaning method for a semiconductor chip (see FIGS. 1 and 2); and
(5e) bonding the cleaned semiconductor chip to an adherend (see FIG. 6).

The embodiment will be mainly described with respect to the points of difference from the fourth embodiment. In the embodiment, in the step (2e), the circuit layer Lc is cut by a laser. Since a laser is used to cut the circuit layer Lc, even when the circuit layer Lc includes a low-k film, peeling of the low-k film can be suppressed. Next, the semiconductor wafer W is cut by blade dicing. The groove G9 illustrated in (c) in FIG. 14 penetrates the semiconductor wafer W and reaches the surface 5f of the adhesive film 5. The grinding swarf generated in the steps (2e) and (3e) can become contaminant that lowers the reliability of the semiconductor device. In the embodiment, grinding swarf generated in these steps can be removed in the subsequent step (4e). The solvent-based, acid-based, or alkaline-based chemical solution is preferably used as the chemical solution.

Although the embodiments of the present disclosure have been described in detail above, the present disclosure is not limited to the above embodiments. For example, in the second, third, fourth, and fifth embodiments, aspects in which the semiconductor wafer W is used as it is without backgrinding have been exemplified, but the semiconductor wafer W may be background prior to arranging the semiconductor wafer W in the region R of the adhesive film 5. That is, in the prescribed embodiments, before arranging the workpiece Pw in the region R provided on the adhesive film 5, the semiconductor wafer W may be ground from a side of the second surface f2 in a state where a backgrinding tape is attached on the workpiece Pw so that the backgrinding tape covers the circuit layer Lc. Also in this case, the circuit layer Lc may include a low-k film.

### REFERENCE SIGNS LIST

1: Base film, 2: Adhesive layer, 5: Adhesive film, 5f: Surface of adhesive film, 10: Substrate (adherend), 20: Resin material, 30: Semiconductor device, 42: Push-up jig, 44: Suction collet, C: Semiconductor chip, C1: Singulated circuit layer, C2: Die, DR: Dicing ring, f1: First surface, f2: Second surface, G1, G2, G3, G4, G5, G6, G7, G8, G9: Groove, Lc: Circuit layer, Mp: Protective film, Pw: Workpiece, R: Region, Rp: Photoresist, TBG: Backgrinding tape, W: Semiconductor wafer, w: Wire

1. A method for cleaning a semiconductor chip, the method comprising:
cleaning a plurality of semiconductor chips with a chemical solution, the semiconductor chips being arranged in a region on a surface of an adhesive film, wherein the region is inside a dicing ring attached to the surface of the adhesive film; and
picking up the cleaned semiconductor chip from the surface,
wherein the chemical solution is one kind selected from the group consisting of solvent-based, acid-based, and alkaline-based chemical solutions.

2. A method for manufacturing a semiconductor device, the method comprising:
forming a photoresist on a workpiece, the workpiece comprising a semiconductor wafer having a first surface and a second surface; and a circuit layer formed on the first surface, so that the photoresist covers the circuit layer;
exposing and developing the photoresist to form a groove reaching the circuit layer in the photoresist;
performing plasma dicing to cut the circuit layer and half-cut the semiconductor wafer through the groove;
removing the photoresist from the circuit layer;
attaching a backgrinding tape so that the backgrinding tape covers the circuit layer;
grinding the semiconductor wafer from a side of the second surface to obtain a plurality of semiconductor chips on a surface of the backgrinding tape;
transferring the semiconductor chips from the surface of the backgrinding tape onto a surface of an adhesive film, and attaching a dicing ring on the surface of the adhesive film so that the dicing ring surrounds the semiconductor chips on the surface;
performing the method for cleaning a semiconductor chip according to claim 1; and
bonding the cleaned semiconductor chip to an adherend.

3. A method for manufacturing a semiconductor device, the method comprising:
arranging a workpiece in a region on a surface of an adhesive film, the workpiece comprising a semiconductor wafer having a first surface and a second surface; and a circuit layer formed on the first surface, wherein the region is inside a dicing ring attached to the surface of the adhesive film;
forming a photoresist so that the photoresist covers the circuit layer;
exposing and developing the photoresist to form a groove reaching the circuit layer in the photoresist;
performing plasma dicing to cut the circuit layer and the semiconductor wafer through the groove to obtain a plurality of semiconductor chips on the surface of the adhesive film;
performing the method for cleaning a semiconductor chip according to claim 1; and
bonding the cleaned semiconductor chip to an adherend.

4. A method for manufacturing a semiconductor device, the method comprising:
arranging a workpiece in a region on a surface of an adhesive film, the workpiece comprising a semiconductor wafer having a first surface and a second surface; and a circuit layer formed on the first surface, wherein the region is inside a dicing ring attached to the surface of the adhesive film;
forming a protective film so that the protective film covers the circuit layer;
cutting the protective film and the circuit layer with a laser to form a groove reaching the first surface;
performing plasma dicing to cut the semiconductor wafer through the groove to obtain a plurality of semiconductor chips on the surface of the adhesive film;
performing the method for cleaning a semiconductor chip according to claim 1; and
bonding the cleaned semiconductor chip to an adherend.

5. The method for manufacturing according to claim 4, wherein the method for cleaning includes removing the protective film.

6. A method for manufacturing a semiconductor device, the method comprising:
arranging a workpiece in a region on a surface of an adhesive film, the workpiece comprising a semiconductor wafer having a first surface and a second surface; and a circuit layer formed on the first surface, wherein the region is inside a dicing ring attached to the surface of the adhesive film;
performing blade dicing to cut the workpiece to obtain a plurality of semiconductor chips on the surface of the adhesive film;
performing the method for cleaning a semiconductor chip according to claim 1; and
bonding the cleaned semiconductor chip to an adherend.

7. A method for manufacturing a semiconductor device, the method comprising:
arranging a workpiece in a region on a surface of an adhesive film, the workpiece comprising a semiconductor wafer having a first surface and a second surface; and a circuit layer formed on the first surface, wherein the region is inside a dicing ring attached to the surface of the adhesive film;
forming a groove in the circuit layer with a laser to singulate the circuit layer into a plurality of singulated circuit layers;
performing blade dicing to cut the semiconductor wafer through the groove to obtain a plurality of semiconductor chips on the surface of the adhesive film;
performing the method for cleaning a semiconductor chip according to claim 1; and
bonding the cleaned semiconductor chip to an adherend.

8. A method for manufacturing a semiconductor device, the method comprising:
arranging a workpiece in a region on a surface of an adhesive film, the workpiece comprising a semiconductor wafer having a first surface and a second surface; and a circuit layer formed on the first surface, wherein the region is inside a dicing ring attached to the surface of the adhesive film;
forming a protective film so that the protective film covers the circuit layer;
cutting the protective film and the circuit layer with a laser to form a groove reaching the first surface;
performing blade dicing to cut the semiconductor wafer through the groove to obtain a plurality of semiconductor chips on the surface of the adhesive film;
performing the method for cleaning a semiconductor chip according to claim 1; and
bonding the cleaned semiconductor chip to an adherend.

9. The method for manufacturing according to claim 8, wherein the method for cleaning includes removing the protective film.

10. The method for manufacturing according to claim 7, wherein the circuit layer formed on the first surface of the semiconductor wafer includes a low-k film.

11. The method for manufacturing according to claim 3, wherein prior to arranging the workpiece in the region on the surface of the adhesive film, the method for manufacturing further comprises grinding the semiconductor wafer from a side of the second surface in a state where a backgrinding tape is attached on the workpiece so that the backgrinding tape covers the circuit layer.

12. The method for cleaning according to claim 1, wherein, prior to cleaning the semiconductor chips with the chemical solution, a groove has been formed by plasma dicing between two adjacent ones of the plurality of semiconductor chips;
at least a portion of a sidewall of the groove, the sidewall constituting a side surface of the semiconductor chip, is covered with a fluorocarbon-based polymer film; and
the fluorocarbon-based polymer film is removed from the semiconductor chip by spraying the chemical solution toward the semiconductor chip from a nozzle.

13. The method for cleaning according to claim 12, wherein, with a spacing between the two adjacent semiconductor chips being widened as compared with before by applying tension to the adhesive film, the chemical solution is supplied to the sidewall of the groove, and the fluorocarbon-based polymer film is removed by the chemical solution.

14. The method for cleaning according to claim 12, wherein the semiconductor chip includes a die and a circuit layer provided to cover one surface of the die, and the semiconductor chip is arranged on the surface of the adhesive film in an orientation in which the die is positioned downward and the circuit layer is positioned upward.

15. The method for cleaning according to claim 12, wherein a work piece is not grounded on the surface of the adhesive film, the work piece being singulated into the semiconductor chips.

16. The method for cleaning according to claim 12, wherein the chemical solution is a hydrofluoroether-based chemical solution.

17. The method for cleaning according to claim 12, wherein the chemical solution is a hydroxylamine-based chemical solution.
